(19) United States
(12) Patent Application Publication
(10) Pub. No.: US 2026/0215296 A1
(43) Pub. Date: Jul. 23, 2026

(54) SEMICONDUCTOR DEVICE

(71) Applicant: FUJI ELECTRIC CO., LTD., Kawasaki-shi (JP)

(72) Inventor: Tomoyuki KANI, Matsumoto-city (JP)

(73) Assignee: FUJI ELECTRIC CO., LTD., Kawasaki-shi (JP)

(21) Appl. No.: 19/402,651

(22) Filed: Nov. 26, 2025

(30) Foreign Application Priority Data
Jan. 21, 2025 (JP) 2025-008376

(51) Int. Cl. H10W 70/60; H10W 90/00

(52) U.S. Cl. CPC H10W 70/611; H10W 90/00; H10W 90/401; H10W 90/701; H10W 90/734

(57) ABSTRACT

A semiconductor device, including: a first output conductive plate through which a first current flows in a first direction; a wiring member, including a bonding portion at one end thereof, to which a second current is input, and a wiring portion which is arranged to be adjacent to and opposite to an upper surface of the first output conductive plate and through which the second current input to the bonding portion flows in a second direction opposite to the first direction.

### CROSS-REFERENCE TO RELATED APPLICATION

This application is based upon and claims the benefit of priority of the prior Japanese Patent Application No. 2025-008376, filed on January 21, 2025, the entire contents of which are incorporated herein by reference.

### BACKGROUND OF THE INVENTION

### Field of the Invention

The embodiments discussed herein relate to a semiconductor device.

### Background of the Related Art

A semiconductor device includes a semiconductor chip, an insulated circuit board on which the semiconductor chip is arranged, and a positive electrode lead frame, a negative electrode lead frame, and an output lead frame to which the semiconductor chip and the insulated circuit board are electrically connected. These lead frames are formed so that directions in which current flows are opposite to one another (see, for example, the following documents (1) to (8)).

(1) Japanese Laid-open Patent Publication No. 2024-066844

(2) Japanese Laid-open Patent Publication No. 2023-075428

(3) Japanese Laid-open Patent Publication No. 2011-023570

(4) Japanese Laid-open Patent Publication No. 2021-132234

(5) International Publication Pamphlet No. WO 2014/208450

(6) Japanese Laid-open Patent Publication No. 2022-006780

(7) International Publication Pamphlet No. WO 2022/224935

(8) International Publication Pamphlet No. WO 2020/261433

### SUMMARY OF THE INVENTION

According to an aspect of the present disclosure, there is provided a semiconductor device, including: a first output conductive plate through which a first current flows in a first direction; and a wiring member, including: a bonding portion at one end thereof, to which a second current is input, and a wiring portion which is arranged to be adjacent to and opposite to an upper surface of the first output conductive plate and through which the second current input to the bonding portion flows in a second direction opposite to the first direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a plan view of an insulated circuit board on which a semiconductor chip is arranged and which is arranged on a heat dissipation base of the first embodiment;

FIG. 3 is a first sectional view of the semiconductor device according to the first embodiment;

FIG. 4 is a second sectional view of the semiconductor device according to the first embodiment;

FIG. 5 is a plan view of a semiconductor device according to the first embodiment (modification 1-1);

FIG. 6 is a sectional view of the semiconductor device according to the first embodiment (modification 1-1);

FIG. 7 is a plan view of a semiconductor device according to the first embodiment (modification 1-2);

FIG. 8 is a sectional view of the semiconductor device according to the first embodiment (modification 1-2);

FIG. 9 is a plan view of insulated circuit boards on which semiconductor chips are arranged and which are arranged on a heat dissipation base of a second embodiment;

FIG. 10 is a plan view of insulated circuit boards on which semiconductor chips are arranged and which are arranged on a heat dissipation base of a third embodiment;

FIG. 11 is a plan view of insulated circuit boards on which semiconductor chips are arranged and which are arranged on a heat dissipation base of a fourth embodiment;

FIG. 12 is a plan view of insulated circuit boards on which semiconductor chips are arranged and which are arranged on a heat dissipation base of a fifth embodiment; and

FIG. 13 is a plan view of insulated circuit boards on which semiconductor chips are arranged and which are arranged on a heat dissipation base of a sixth embodiment.

### DETAILED DESCRIPTION OF THE INVENTION

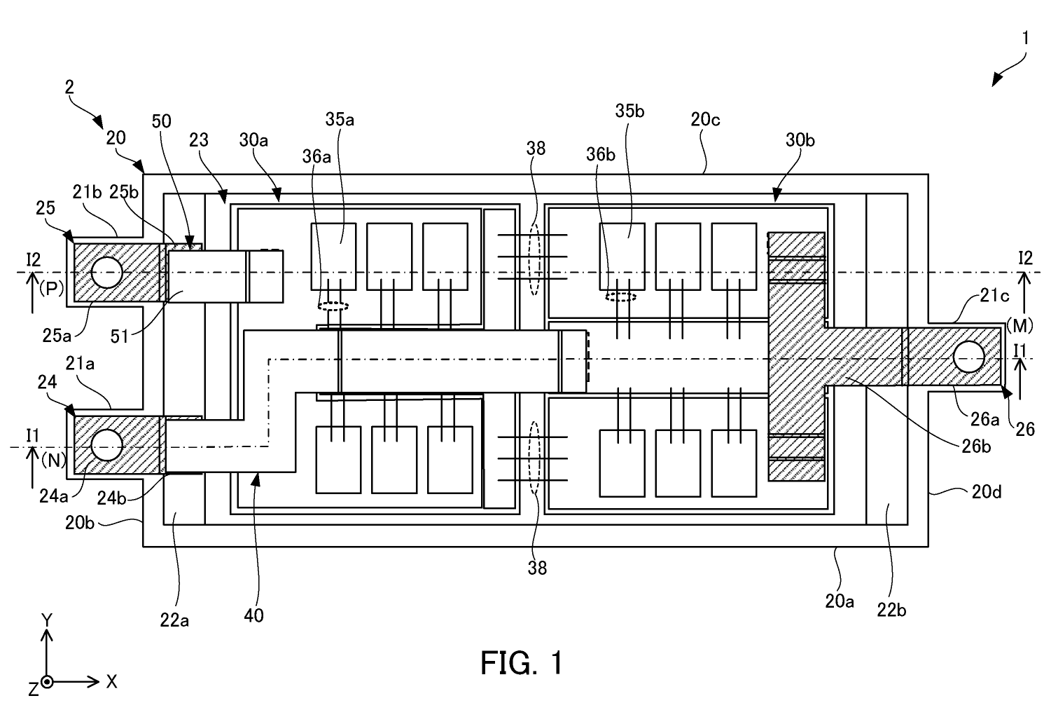

Embodiments will now be described with reference to the drawings. In the following description, a “front surface” or an “upper surface” represents an X-Y plane facing upward (+Z direction) in the semiconductor device 1 of FIGS. 1, 3, and 4. Similarly, an “upside” represents an upward direction (+Z direction) in the semiconductor device 1 of FIGS. 1, 3, and 4. A “back surface” or a “lower surface” represents the X-Y plane facing downward (−Z direction) in the semiconductor device 1 of FIGS. 1, 3, and 4. Similarly, a “downside” represents a downward direction (−Z direction) in the semiconductor device 1 of FIGS. 1, 3, and 4. The term “higher” or “upper” represents a position on the upper side (+Z direction) in the semiconductor device 1 of FIGS. 1, 3, and 4. Similarly, the term “lower” or “under” represents a position on the lower side (−Z direction) in the semiconductor device 1 of FIGS. 1, 3, and 4. The terms “front surface”, “upper surface”, “upside” and “back surface”, “lower surface”, “downside” and “side surface” are mere expressions for convenience of specifying a relative positional relationship, and do not limit the technical idea of the present disclosure. For example, “upside” or “downside” does not always mean the vertical direction with respect to the ground. That is to say, a direction represented by the “upside” or “downside” is not limited to the gravity direction. The same directionality that is described above is meant in the other drawings at need. In addition, in the following description, a “main component” represents a component contained at a rate of 80 vol% or more. Furthermore, “substantially the same” may be within the range of ±10%. In addition, “perpendicular”, “orthogonal”, and “parallel” may be within the range of ±10°. In the drawings, the same components are marked with the same reference numerals and description thereof may be omitted or simplified. In addition, in the drawings, reference numerals of components already described may be omitted.

### First Embodiment

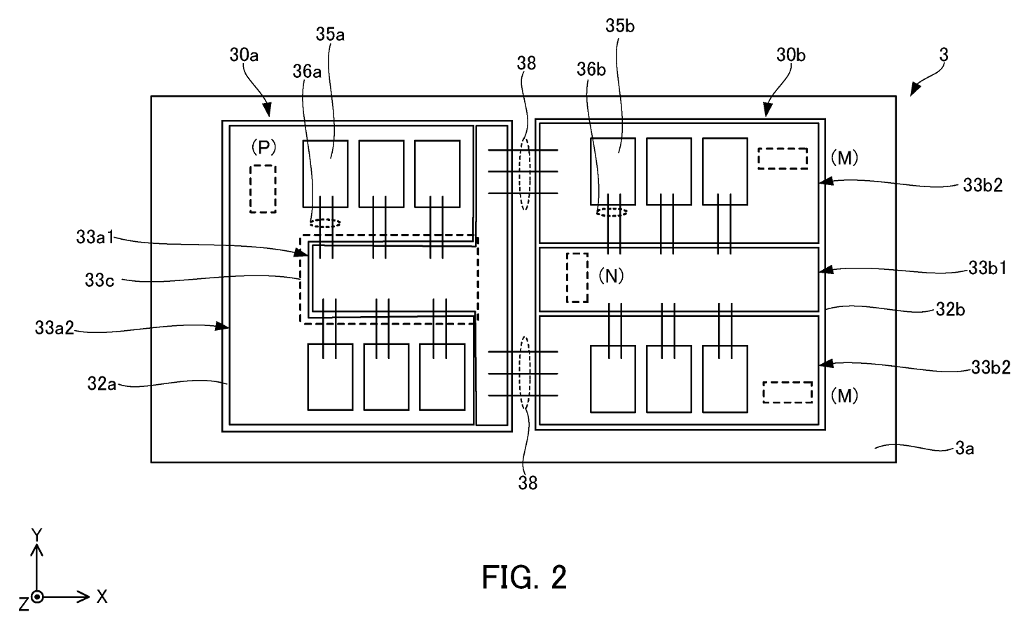

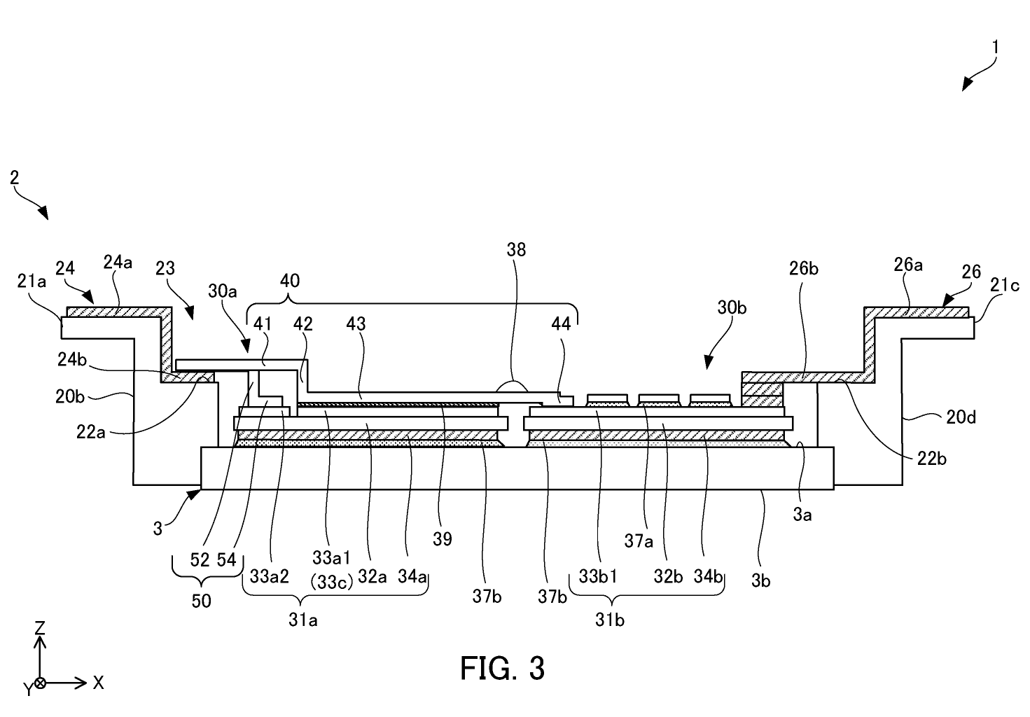

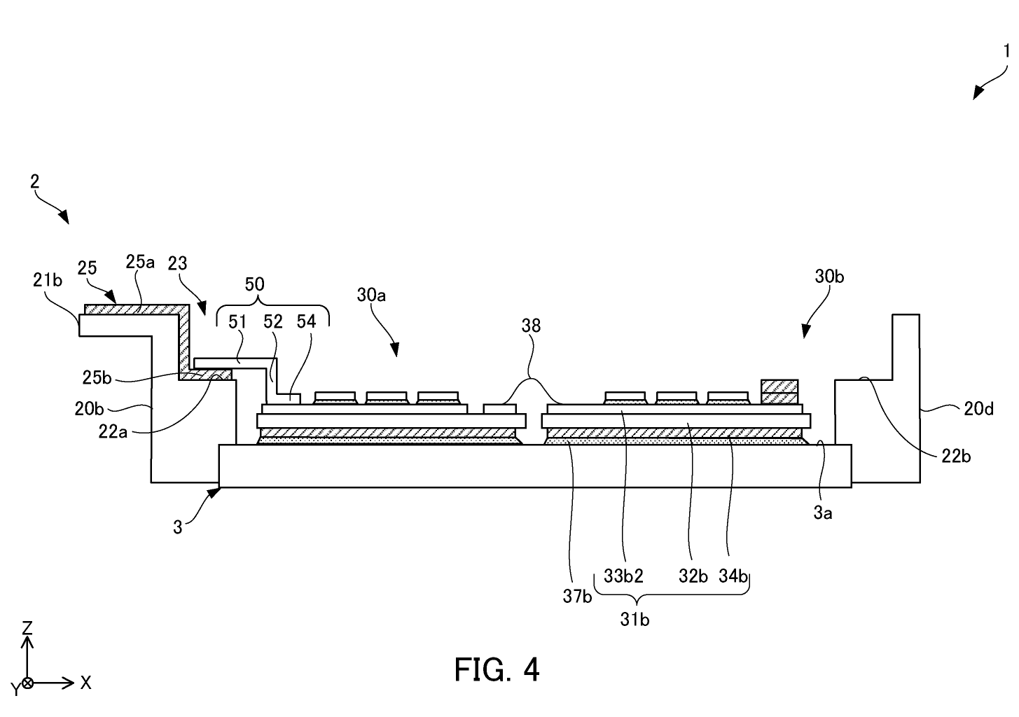

A semiconductor device 1 according to a first embodiment will be described with reference to FIGS. 1 to 4. FIG. 1 is a plan view of a semiconductor device according to a first embodiment. FIG. 2 is a plan view of an insulated circuit board on which a semiconductor chip is arranged and which is arranged on a heat dissipation base of the first embodiment. FIG. 3 is a first sectional view of the semiconductor device according to the first embodiment. FIG. 4 is a second sectional view of the semiconductor device according to the first embodiment. In the semiconductor device 1 illustrated in FIGS. 1 to 4, a sealing member is not illustrated. FIGS. 3 and 4 are sectional views taken along dot-dash lines I1-I1 and I2-I2, respectively, of FIG. 1.

The semiconductor device 1 includes a heat dissipation base 3, semiconductor units 30a and 30b, and lead frames 40 and 50. Furthermore, the semiconductor device 1 includes a case 2 which is formed on the heat dissipation base 3 and which houses the semiconductor units 30a and 30b and the lead frames 40 and 50.

The heat dissipation base 3 has the shape of a flat plate and includes an upper surface 3a and a lower surface 3b having a rectangular shape in plan view. The upper surface 3a and the lower surface 3b may be approximately flat. The heat dissipation base 3 includes sides (long sides) in the longitudinal direction, that is to say, in the ±X directions and sides (short sides) in the lateral direction, that is to say, in the ±Y directions. The heat dissipation base 3 is made of metal, such as copper, aluminum, or an alloy containing at least one of them, having excellent thermal conductivity. Furthermore, in order to improve corrosion resistance, the surface of the heat dissipation base 3 may be plated. A plating material is, for example, nickel, a nickel-phosphorus alloy, or a nickel-boron alloy.

The semiconductor units 30a and 30b include insulated circuit boards 31a and 31b and semiconductor chips 35a and 35b arranged on the insulated circuit boards 31a and 31b, respectively. The semiconductor units 30a and 30b may have the same structure.

The insulated circuit boards 31a and 31b have the same shape and the same size in plan view. The insulated circuit boards 31a and 31b include insulating plates 32a and 32b, conductive circuit patterns 33a1 and 33a2, and 33b1 and 33b2, and metal plates 34a and 34b, respectively. The insulating plates 32a and 32b and the metal plates 34a and 34b have a rectangular shape in plan view. Furthermore, corner portions of the insulating plates 32a and 32b and the metal plates 34a and 34b may be R-chamfered or C-chamfered. The size of the metal plates 34a and 34b is smaller than the size of the insulating plates 32a and 32b in plan view and the metal plates 34a and 34b are formed inside the insulating plates 32a and 32b, respectively. The upper surfaces of the insulated circuit boards 31a and 31b may be the upper surfaces of the conductive circuit patterns 33a1 and 33a2, and 33b1 and 33b2, respectively. The lower surfaces of the insulated circuit boards 31a and 31b may be the lower surfaces of the metal plates 34a and 34b, respectively.

The insulating plates 32a and 32b may be ceramic plate boards made of ceramics. The ceramic plate boards are made of a ceramic having good thermal conductivity. The ceramics contain, for example, aluminum oxide, aluminum nitride, or silicon nitride as a main component. For example, a direct copper bonding (DCB) substrate or an active metal brazed (AMB) substrate may be used as the insulated circuit boards 31a and 31b (first and second insulated circuit boards) including the insulating plates 32a and 32b, respectively, having the above structure.

Alternatively, the insulating plates 32a and 32b (first and second insulating plates) may be made of resin. The resin may have low thermal resistance and a high insulating property. Examples of such a resin include a thermosetting resin and a thermoplastic resin. Such a resin may further contain a filler. The thermal resistance of the insulating plates 32a and 32b is reduced further by controlling a material for the filler and filler content. Furthermore, the linear expansion coefficient of the insulating plates 32a and 32b is made approximately equal to the linear expansion coefficient of the conductive circuit patterns 33a1, 33a2, 33b1, and 33b2 and the metal plates 34a and 34b according to the filler. By reducing the difference between the linear expansion coefficients in this way, the occurrence of a warp of the insulated circuit boards 31a and 31b caused by the difference between the linear expansion coefficients is reduced even when the temperature changes.

For example, the thermosetting resin is at least one of epoxy resin, cyanate resin, benzoxazine resin, unsaturated polyester resin, phenolic resin, melamine resin, silicone resin, and a maleimide resin. The thermoplastic resin is at least one of polyimide resin, acrylic resin, and polyamide resin. The filler is made of at least one of an oxide and a nitride. For example, the oxide is silicon oxide or aluminum oxide. For example, the nitride is silicon nitride, aluminum nitride, or boron nitride. Furthermore, hexagonal boron nitride may be used as the filler.

The metal plates 34a and 34b are made of metal, such as copper, aluminum, and an alloy containing at least one of them, having excellent thermal conductivity. In this case, copper is contained. Furthermore, in order to improve corrosion resistance, the surfaces of the metal plates 34a and 34b may be plated. A plating material is, for example, nickel, a nickel-phosphorus alloy, or a nickel-boron alloy.

The conductive circuit patterns 33a1 and 33a2, and 33b1 and 33b2 are formed over the entire surfaces of the insulating plates 32a and 32b, respectively, except edge portions thereof. Preferably, end portions of the conductive circuit patterns 33a1 and 33a2, and 33b1 and 33b2 facing the outer peripheries of the insulating plates 32a and 32b are superimposed in plan view over outer periphery-side end portions of the metal plates 34a and 34b, respectively. Therefore, with the insulated circuit boards 31a and 31b, a stress balance between the conductive circuit patterns 33a1 and 33a2 on the upper surface of the insulating plate 32a and the metal plate 34a on the lower surface of the insulating plate 32a and between the conductive circuit patterns 33b1 and 33b2 on the upper surface of the insulating plate 32b and the metal plate 34b on the lower surface of the insulating plate 32b are maintained. Damage, such as an excessive warp or a crack, to the insulating plates 32a and 32b is further suppressed.

The conductive circuit patterns 33a1, 33a2, 33b1, and 33b2 are made of metal, such as copper, aluminum, or an alloy containing at least one of them as a main component, having excellent electrical conductivity. The surfaces of the conductive circuit patterns 33a1, 33a2, 33b1, and 33b2 may be plated in order to improve corrosion resistance. At this time, for example, nickel, a nickel-phosphorus alloy, or a nickel-boron alloy is used as a plating material.

The conductive circuit pattern 33a1 (first output conductive plate) has the shape of the letter “T” in plan view and is formed close to a side of the insulating plate 32a in the +X direction in FIG. 2. The conductive circuit pattern 33a1 includes a protrusion 33c protruding in the −X direction.

The conductive circuit pattern 33a2 has the shape of the letter “U” in plan view and is formed close to a side of the insulating plate 32a in the −X direction in FIG. 2. The protrusion 33cof the conductive circuit pattern 33a1 is combined with a recess of the conductive circuit pattern 33a2. Furthermore, an area (P) surrounded by a broken line of the conductive circuit pattern 33a2 is an example of a position to which an external connection terminal 25 to which a positive electrode of an external power supply described later is connected is electrically connected.

The conductive circuit pattern 33b1 (second output conductive plate) has the shape of the letter “I” in plan view and is formed at the center of the insulating plate 32b so as to be parallel to the ±X directions. Furthermore, a region (N) surrounded by a broken line of the conductive circuit pattern 33b1 is an example of a position to which a lead frame 40 connected to an external connection terminal 24 to which a negative electrode of the external power supply described later is connected is electrically connected.

The conductive circuit patterns 33b2 have the shape of the letter “I” in plan view, are parallel to the insulating plate 32b in the ±X directions, and are formed with the conductive circuit pattern 33b1 therebetween. Furthermore, an area (M) surrounded by a broken line of each conductive circuit pattern 33b2 is an example of a position connected to an external connection terminal 26 connected to an external load described later.

The protrusion 33c of the conductive circuit pattern 33a1 and the conductive circuit pattern 33b1 may have approximately the same width in the ±Y directions. In addition, the width of the conductive circuit pattern 33b2 in the ±Y directions may be approximately equal to the width of a portion, which sandwiches the recess, of the conductive circuit pattern 33a2 in the ±Y directions. That is to say, the width in the ±Y directions of each of areas formed in the ±Y directions of the recess of the conductive circuit pattern 33a2 may be approximately equal to the width in the ±Y directions of each of the two conductive circuit patterns 33b2 formed on both sides in the ±Y directions with the conductive circuit pattern 33b1 therebetween.

The shapes, number, and arrangement positions of the conductive circuit patterns 33a1, 33a2, 33b1, and 33b2 are mere examples. The shapes, the number, and the arrangement positions described in the first embodiment are not always used at need. Examples of other conductive circuit patterns will be described later.

Furthermore, semiconductor chips 35a and 35b are arranged on the conductive circuit patterns 33a2 and 33b2, respectively. In this example, six semiconductor chips 35a and six semiconductor chips 35b are arranged in two rows.

Each of the semiconductor chips 35a and 35b (first and second semiconductor chips) may include a switching element which is a power metal-oxide-semiconductor field-effect transistor (MOSFET) containing silicon carbide as a main component. Each of the semiconductor chips 35a and 35b includes a control electrode (gate electrode or the like) and an output electrode (source electrode) (first and second output electrodes) as a main electrode on the upper surface (not illustrated). Each of the semiconductor chips 35a and 35b includes an input electrode (drain electrode) (first and second input electrodes) as a main electrode on the lower surface (not illustrated). Each of the semiconductor chips 35a and 35b may contain gallium nitride as a main component. A control electrode may be formed along one side (or at a central portion of one side) of an upper surface of each of the semiconductor chips 35a and 35b. An output electrode may be formed at a central portion of an upper surface of each of the semiconductor chips 35a and 35b.

Each of the semiconductor chips 35a and 35b includes a power device element containing silicon as a main component. The power device element is a reverse-conducting insulated gate bipolar transistor (RC-IGBT). The RC-IGBT has both functions of an IGBT, which is a switching element, and a free wheeling diode (FWD), which is a diode element. A control electrode (gate electrode or the like) and an output electrode (emitter electrode) as a main electrode (not illustrated) are formed on an upper surface of each of the semiconductor chips 35a and 35b. An input electrode (collector electrode) as a main electrode (not illustrated) is formed on a lower surface of each of the semiconductor chips 35a and 35b. A control electrode may be formed along one side (or at a central portion of one side) of an upper surface of each of the semiconductor chips 35a and 35b. An output electrode may be formed at a central portion of an upper surface of each of the semiconductor chips 35a and 35b.

The same number of semiconductor chips 35a are arranged on the conductive circuit pattern 33a2 in plan view with the recess of the conductive circuit pattern 33a2 (protrusion 33c of the conductive circuit pattern 33a1) therebetween and the output electrodes facing inward (toward the protrusion 33c). Furthermore, the output electrodes of the semiconductor chips 35a and the protrusion 33c of the conductive circuit pattern 33a1 are electrically connected by wires 36a.

The same number of semiconductor chips 35b are arranged on the conductive circuit pattern 33b2 in plan view with the conductive circuit pattern 33b1 therebetween and the output electrodes facing inward (toward the conductive circuit pattern 33b1). Furthermore, the output electrodes of the semiconductor chips 35b and the conductive circuit pattern 33b1 are electrically connected by wires 36b.

The wires 36a and 36b contain a material, such as gold, copper, aluminum, or an alloy containing at least one of them, having excellent electrical conductivity as a main component. Preferably, the wires 36a and 36b may be made of an aluminum alloy containing a very small amount of silicon.

Furthermore, the semiconductor chips 35a and 35b are fixed to the conductive circuit patterns 33a2 and 33b2, respectively, by bonding members 37a. The bonding members 37a may be solder. Lead-free solder is used as the solder. The lead-free solder contains, for example, an alloy containing at least two of tin, silver, copper, zinc, antimony, indium, and bismuth as a main component. Moreover, the solder may contain an additive. The additive is, for example, nickel, germanium, cobalt, or silicon. When the solder contains an additive, wettability, gloss, and bonding strength are improved and reliability is improved. In addition, a sintered body may be used as the bonding members 37a. If a sintered body is used for bonding, then a sintered material is, for example, silver, iron, copper, aluminum, titanium, nickel, tungsten, or molybdenum powder.

The semiconductor units 30a and 30b are arranged on the upper surface 3a of the heat dissipation base 3. The semiconductor units 30a and 30b are arranged along the longitudinal direction of the heat dissipation base 3. The semiconductor units 30a and 30b are arranged so that the conductive circuit pattern 33a1 of the insulated circuit board 31a and the conductive circuit patterns 33b1 and 33b2 of the insulated circuit board 31b are opposite to each other. At this time, the metal plates 34a and 34b of the insulated circuit boards 31a and 31b of the semiconductor units 30a and 30b, respectively, are bonded to the upper surface 3a of the heat dissipation base 3 by the bonding members 37b. The bonding members 37b may be made of the same material as the bonding members 37a.

Furthermore, on the heat dissipation base 3, the conductive circuit pattern 33a1 of the semiconductor unit 30a and the two conductive circuit patterns 33b2 of the semiconductor unit 30b are electrically connected to each other by wires 38. The wire 38 extends along the longitudinal direction of the heat dissipation base 3. The wire 38 may be made of the same material as the wires 36a and 36b.

The case 2 includes a frame portion 20 and the external connection terminals 24, 25, and 26. The frame portion 20 has a frame shape in plan view and includes side portions 20a, 20b, 20c, and 20d, terminal blocks 21a, 21b, and 21c, and level differences 22a and 22b.

The side portions 20a, 20b, 20c, and 20d surround the four sides of the frame portion 20 to form a housing region 23. The side portions 20a and 20c extend along the longitudinal direction of the frame portion 20 in plan view and may correspond, in this case, to long sides. The side portions 20b and 20d extend along the lateral direction of the frame portion 20 in plan view and may correspond, in this case, to short sides. Each of the side portions 20a, 20b, 20c, and 20d may include an outer surface, an inner surface, an upper surface, and a lower surface (reference numerals thereof are omitted). The outer surface is a surface facing the outside of the frame portion 20. The inner surface is a surface facing the housing region 23 of the frame portion 20. The upper surface and the lower surface have a frame shape in plan view and the lower surface is bonded to the upper surface 3a of the heat dissipation base 3 with an adhesive. The side portions 20a, 20b, 20c, and 20d are integrally connected. Connection portions of the side portions 20a, 20b, 20c, and 20d may be R-chamfered or C-chamfered.

The terminal blocks 21a and 21b are formed on the outer surface of the side portion 20b so as to be flush with the upper surface of the side portion 20b. The terminal blocks 21a and 21b extend outward (in the −X direction in FIG. 1) from the outer surface of the side portion 20b. External connection portions 24a and 25a of the external connection terminals 24 and 25 described later are arranged on the terminal blocks 21a and 21b, respectively.

The terminal block 21c is formed on the outer surface of the side portion 20d so as to be flush with the upper surface of the side portion 20d. The terminal block 21c extends outward (in the +X direction in FIG. 1) from the outer surface of the side portion 20d. An external connection portion 26a of the external connection terminal 26 described later is arranged on the terminal block 21c.

The arrangement positions, shapes, and number of the terminal blocks 21a, 21b, and 21c are mere examples and are not limited to those in FIG. 1. The terminal blocks 21a, 21b, and 21c may be arranged at arbitrary positions of the frame portion 20 according to the design of the semiconductor device 1. Furthermore, the arrangement positions, shapes, and number of the external connection terminals 24, 25, and 26 described later may also correspond to the arrangement positions, shapes, and number of the terminal blocks 21a, 21b, and 21c, respectively.

The level differences 22a and 22b are formed on the inner surfaces of the side portions 20b and 20d, between the side portions 20a and 20c, and below (on the −Z direction side of) the upper surfaces of the side portions 20b and 20d, respectively. The surfaces of the level differences 22a and 22b are parallel to the X-Y plane and may be approximately flat. Bonding portions 24b and 25b of the external connection terminals 24 and 25, respectively, are arranged on the level difference 22a. A bonding portion 26b of the external connection terminal 26 is arranged on the level difference 22b.

The external connection terminals 24, 25, and 26 are made of metal, such as copper, aluminum, or an alloy containing at least one of them as a main component, having excellent electrical conductivity. The surfaces of the external connection terminals 24, 25, and 26 may be plated in order to improve corrosion resistance. At this time, for example, nickel, a nickel-phosphorus alloy, or a nickel-boron alloy is used as a plating material.

A negative power supply terminal (N) and a positive power supply terminal (P) of the external power supply are connected to the external connection terminals 24 and 25, respectively. The external connection terminals 24 and 25 have a flat plate shape, form a straight line shape in plan view, and integrally include the external connection portions 24a and 25a and the bonding portions 24b and 25b, respectively. The external connection portions 24a and 25a are arranged on the terminal blocks 21a and 21b, respectively, of the frame portion 20. The bonding portions 24b and 25b are integrally connected to the external connection portions 24a and 25a, respectively, and are arranged on the level difference 22a along the inner surface of the side portion 20b (or included in the side portion 20b).

An external load (M) is connected to the external connection terminal 26. The external connection terminal 26 has a flat plate shape, has the shape of the letter “T” in plan view, and includes the external connection portion 26a and the bonding portion 26b. The external connection portion 26a is arranged on the terminal block 21c of the frame portion 20. The bonding portion 26b is integrally connected to the external connection portion 26a and is arranged on the level difference 22b along the inner surface of the side portion 20d (or included in the side portion 20d). Furthermore, the bonding portion 26b branches in the ±Y directions in the housing region 23, extends to each of the branches, and is bonded to each of the two conductive circuit patterns 33b2.

With the case 2, the frame portion 20 including the external connection terminals 24, 25, and 26 is integrally molded by injection molding by the use of a thermoplastic resin. At this time, the frame portion 20 is integrally molded with the side portions 20a, 20b, 20c, and 20d, the terminal blocks 21a, 21b, and 21c, and the level differences 22a and 22b. The thermoplastic resin is, for example, polyphenylene sulfide resin, polybutylene terephthalate resin, polybutylene succinate resin, polyamide resin, or acrylonitrile butadiene styrene resin.

Control terminals (not illustrated) are formed on the case 2. The control terminals may also be integrally molded with the frame portion 20. The control terminals are electrically connected to the control electrodes of the semiconductor chips 35a and 35b in the case 2.

The lead frames 40 and 50 are made of metal, such as copper, aluminum, or an alloy containing at least one of them as a main component, having excellent electrical conductivity. The surfaces of the lead frames 40 and 50 may be plated in order to improve corrosion resistance. At this time, for example, nickel, a nickel-phosphorus alloy, or a nickel-boron alloy is used as a plating material.

The lead frame 40 electrically connects the external connection terminal 24 and the conductive circuit pattern 33b1. The lead frame 40 has a flat plate shape and integrally includes a bonding portion 41, a rising portion 42, a wiring portion 43, and a bonding portion 44.

The bonding portion 41 has a crank shape in plan view and is parallel to the upper surface 3a of the heat dissipation base 3. One end of the bonding portion 41 is bonded to the bonding portion 24b of the external connection terminal 24 on the level difference 22a and the other end is integrally connected to the rising portion 42. The bonding portion 41 may be bonded to the bonding portion 24b of the external connection terminal 24 by, for example, ultrasonic welding or laser welding or by soldering. In the following description, bonding between an external connection terminal and a lead frame and bonding between a lead frame and a conductive circuit pattern may be performed by ultrasonic welding or laser welding or may be performed by soldering.

The bonding portion 41 extends from the one end to the housing region 23 perpendicularly to the side portion 20b and is bent at right angles toward the center side (in the +Y direction) of the insulated circuit board 31a on this side of the region where the semiconductor chips 35a of the conductive circuit pattern 33a2 are arranged. The bonding portion 41 is further bent at right angles in the +X direction, extends toward the protrusion 33c of the conductive circuit pattern 33a1, and is connected to an upper end of the rising portion 42.

The rising portion 42 extends perpendicularly from the other end of the bonding portion 41 toward the upper surface 3a of the heat dissipation base 3 and is connected to one end of the wiring portion 43. The rising portion 42 may be, for example, over the protrusion 33c of the conductive circuit pattern 33a1 in plan view. In FIG. 3, the rising portion 42 is located over an end portion in the −X direction of the protrusion 33c of the conductive circuit pattern 33a1.

The wiring portion 43 extends from a lower end of the rising portion 42 to the conductive circuit pattern 33b1 across a space between the insulated circuit board 31a and the insulated circuit board 31b along the upper surface 3a and the long sides of the heat dissipation base 3 and is connected to the bonding portion 44. The width of the wiring portion 43 in the ±Y directions may be approximately equal to or smaller than the width of the protrusion 33c of the conductive circuit pattern 33a1 in the ±Y directions.

There is a gap between the wiring portion 43 and the conductive circuit pattern 33a1 (protrusion 33c). The gap is, for example, preferably 3 mm or less, and more preferably 1 mm. The wiring portion 43 and the protrusion 33c of the conductive circuit pattern 33a1 are adjacent to and opposite to each other in this way. An insulating member 39 is formed in this gap. The insulating member 39 may be formed in the entire region where the wiring portion 43 is superimposed over the protrusion 33c of the conductive circuit pattern 33a1. The insulating member 39 may be made of an insulating material. The insulating member 39 may be, for example, an insulating sheet, and an adhesive layer may be formed on one main surface of the insulating sheet.

The wires 36a may be connected at a sufficient distance from the wiring portion 43 of the lead frame 40. By doing so, insulation distance between the wires 36a and the wiring portion 43 of the lead frame 40 is maintained.

The bonding portion 44 is connected to the other end of the wiring portion 43 and is bonded to the conductive circuit pattern 33b1. The bonding portion 44 may be integrally connected to the wiring portion 43 with a level difference therebetween.

The lead frame 50 electrically connects the external connection terminal 25 and the conductive circuit pattern 33a2. The lead frame 50 has a flat plate shape and integrally includes a bonding portion 51, a rising portion 52, and a bonding portion 54. The bonding portion 51 has a linear shape in plan view and is parallel to the upper surface 3a of the heat dissipation base 3. One end of the bonding portion 51 is bonded to the bonding portion 25b of the external connection terminal 25 over the level difference 22a, and the other end is integrally connected to the rising portion 52. The bonding portion 51 extends from the one end to the housing region 23 perpendicularly to the side portion 20b, extends to the conductive circuit pattern 33a2, and is connected to an upper end of the rising portion 52.

The rising portion 52 extends perpendicularly from the other end of the bonding portion 51 toward the upper surface 3a of the heat dissipation base 3 and is connected to one end of the bonding portion 54. The rising portion 52 may be located in plan view, for example, near an end portion of the conductive circuit pattern 33a2 on the side of the side portion 20b (in the −X direction). One end of the bonding portion 54 is connected to a lower end of the rising portion 52 and is bonded to the conductive circuit pattern 33a2.

Furthermore, with the semiconductor device 1, the housing region 23 of the case 2 is filled with a sealing member (not illustrated) to seal the housing region 23. The sealing member may be a silicone gel or a thermosetting resin. The thermosetting resin is, for example, epoxy resin, phenolic resin, maleimide resin, or polyester resin. The sealing member does not need to seal the entire inside of the housing region 23, and need only seal the lead frames 40 and 50 and an upper surface of the bonding portion 26b of the external connection terminal 26.

The above semiconductor device 1 includes the conductive circuit pattern 33a1 in which a first current is conducted in the +X direction, which is an example of a first direction, and the lead frame 40 including the bonding portion 44 at one end to which a second current is input and the wiring portion 43 which is arranged adjacently to and opposite to an upper surface of the conductive circuit pattern 33a1 and in which the second current input to the bonding portion 44 is conducted in the −X direction, which is an example of a second direction opposite to the first direction.

With this semiconductor device 1, the negative electrode of the external power supply is connected to the external connection portion 24a of the external connection terminal 24 and the positive electrode of the external power supply is connected to the external connection portion 25a of the external connection terminal 25. In response to a control signal input to the control electrodes of the semiconductor chips 35a and 35b, the first current output from the output electrodes of the semiconductor chips 35a flows into the protrusion 33c of the conductive circuit pattern 33a1 via the wires 36a and energizes the protrusion 33c in the +X direction. The first current flows from the conductive circuit pattern 33a1 into the conductive circuit pattern 33b2 via the wires 38. The first current flowing into the conductive circuit pattern 33b2 is input to the input electrodes on the back surfaces of the semiconductor chips 35b.

Furthermore, when the sum of the first current and a current flowing from the external connection terminal 26 is input to the input electrodes, the semiconductor chips 35b output the second current from the output electrodes on the upper surfaces. The second current flows into the conductive circuit pattern 33b1 via the wires 36b and energizes the conductive circuit pattern 33b1 in the −X direction. The second current which energizes the conductive circuit pattern 33b1 in the −X direction is input from the bonding portion 44 to the lead frame 40. The second current energizes the wiring portion 43 of the lead frame 40 in the −X direction.

At this time, the first current energizes the conductive circuit pattern 33a1 in the +X direction and the second current energizes the wiring portion 43 of the lead frame 40 in the −X direction. Furthermore, the conductive circuit pattern 33a1 and the wiring portion 43 of the lead frame 40 are adjacent to each other. Therefore, the inductance of wirings through which the first and second currents flow is reduced. As described above, with the semiconductor device 1, because the conductive circuit pattern 33a1 and the lead frame 40 are adjacent to each other, inductance is reduced.

Various modifications of the semiconductor device 1 according to the first embodiment will now be described with reference to the drawings. In the modifications, components which are the same as those of the semiconductor device 1 according to the first embodiment are marked with the same reference numerals, and the description thereof may be omitted or simplified.

### Modification 1-1

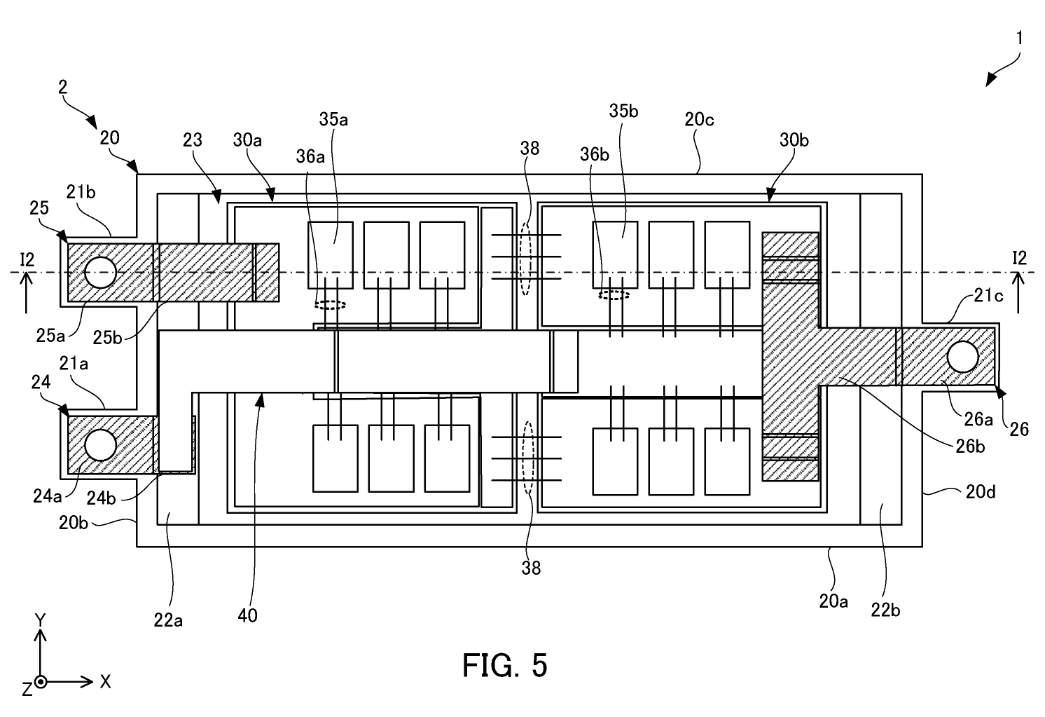

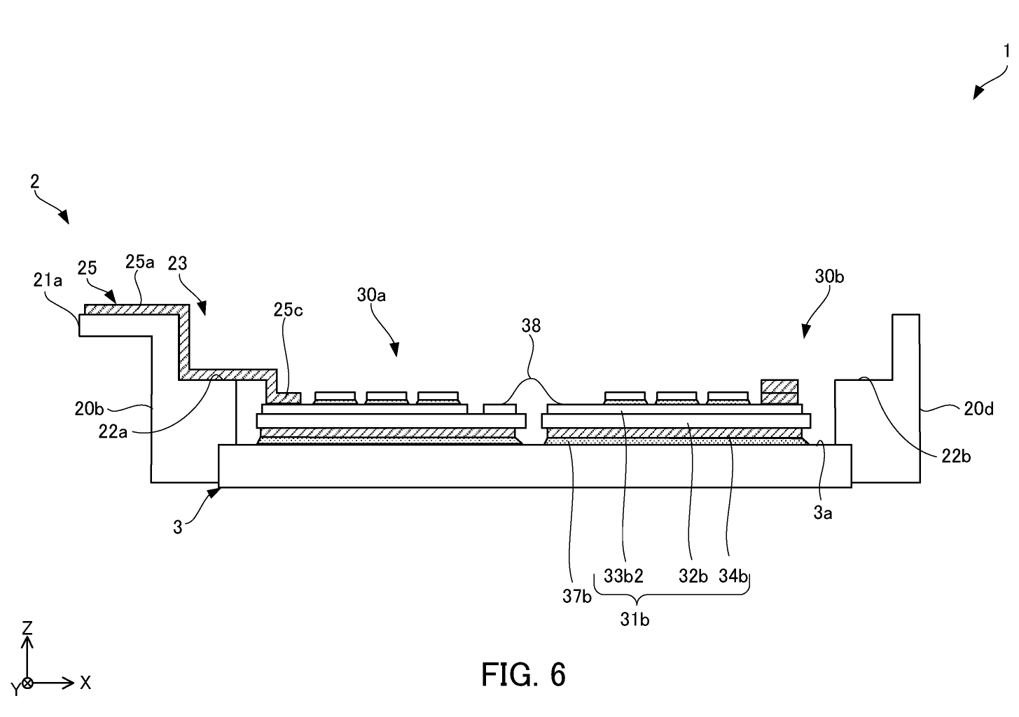

A semiconductor device according to the first embodiment (modification 1-1) will be described with reference to FIGS. 5 and 6. FIG. 5 is a plan view of a semiconductor device according to the first embodiment (modification 1-1). FIG. 6 is a sectional view of the semiconductor device according to the first embodiment (modification 1-1). FIG. 6 is a sectional view taken along the dot-dash line I2-I2 in FIG. 5.

With the semiconductor device 1 according to modification 1-1, the external connection terminal 25 of the semiconductor device 1 according to the first embodiment is directly bonded to the conductive circuit pattern 33a2 without using the lead frame 50. With the semiconductor device 1 according to modification 1-1, the number of components is reduced compared with the semiconductor device 1 according to the first embodiment. Furthermore, there is no need to bond the lead frame 50, and the number of manufacturing processes is reduced. Therefore, manufacturing costs are reduced.

### Modification 1-2

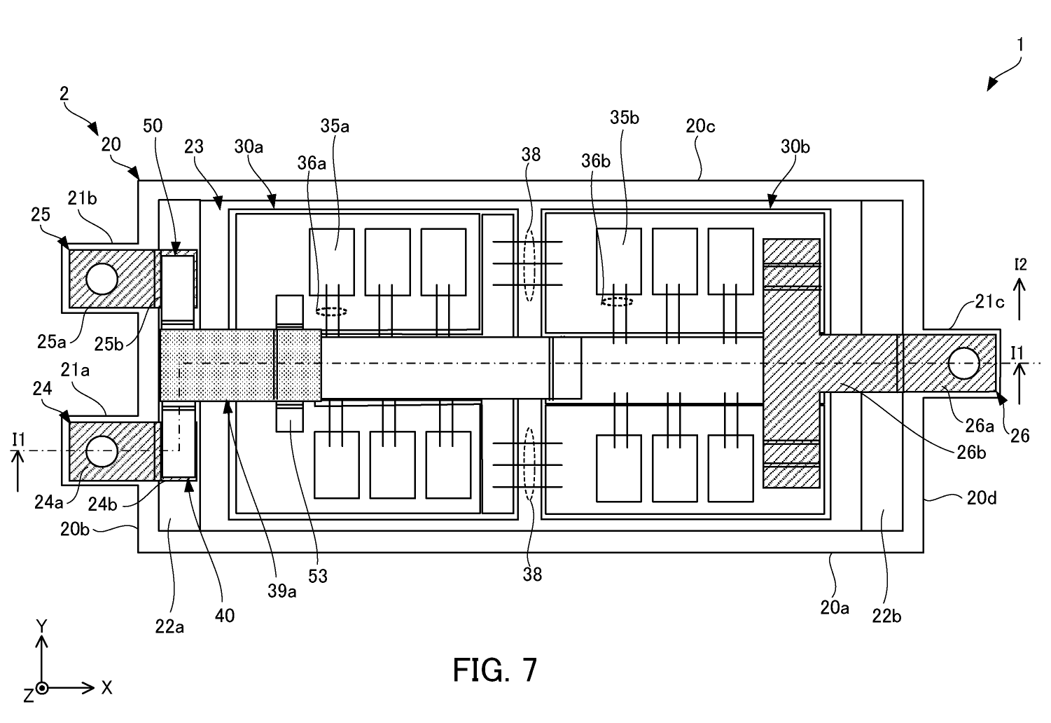

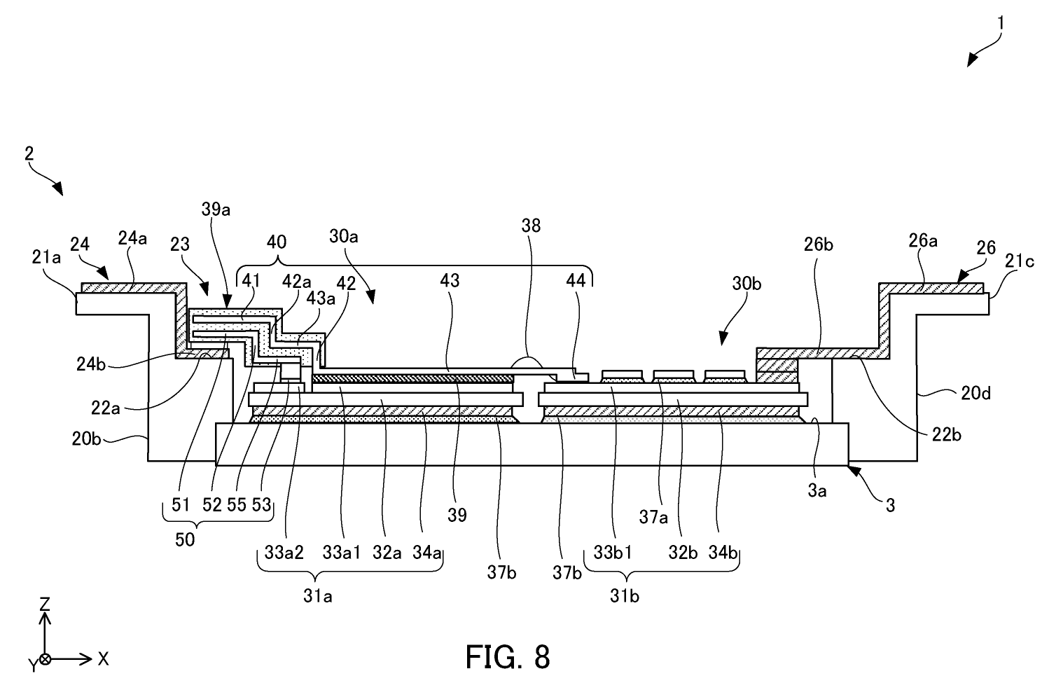

A semiconductor device according to the first embodiment (modification 1-2) will be described with reference to FIGS. 7 and 8. FIG. 7 is a plan view of a semiconductor device according to the first embodiment (modification 1-2). FIG. 8 is a sectional view of the semiconductor device according to the first embodiment (modification 1-2). FIG. 8 is a sectional view taken along the dot-dash line I1-I1 in FIG. 7.

With the semiconductor device 1 according to modification 1-2, lead frames 40 and 50 differ from the lead frames 40 and 50, respectively, of the semiconductor device 1 according to the first embodiment. The lead frame 40 of the semiconductor device 1 according to modification 1-2 also electrically connects an external connection terminal 24 and a conductive circuit pattern 33b1. The lead frame 40 also includes a bonding portion 41, a rising portion 42, a wiring portion 43, and a bonding portion 44. Furthermore, the lead frame 40 includes a rising portion 42a and a wiring portion 43a.

The bonding portion 41 has an L shape in plan view and is parallel to an upper surface 3a of a heat dissipation base 3. One end of the bonding portion 41 is bonded to a bonding portion 24b of an external connection terminal 24 on a level difference 22a, and the other end is integrally connected to the rising portion 42a. The bonding portion 41 extends from the one end in the +Y direction along a side portion 20b on the level difference 22a, and is bent at right angles toward a housing region 23 side at a central portion in the ±Y directions of the level difference 22a. A bent portion of the bonding portion 41 extends toward a protrusion 33c of a conductive circuit pattern 33a1 and is connected to an upper end of the rising portion 42a.

The rising portion 42a extends perpendicularly from the other end of the bonding portion 41 toward the upper surface 3a of the heat dissipation base 3 and is connected to one end of the wiring portion 43a. For example, the rising portion 42a may be located over a conductive circuit pattern 33a2 in plan view and in a side view.

One end of the wiring portion 43a is connected to a lower end of the rising portion 42a and extends from the lower end toward the conductive circuit pattern 33a1 along the upper surface 3a and long sides of the heat dissipation base 3. The other end of the wiring portion 43a is connected to an upper end of the rising portion 42.

The rising portion 42 extends perpendicularly from the other end of the wiring portion 43a toward the upper surface 3a of the heat dissipation base 3 and is connected to one end of the wiring portion 43. For example, the rising portion 42 may be located over the conductive circuit pattern 33a1 in plan view and in a side view. In FIG. 7, the rising portion 42 is located near an end portion of the conductive circuit pattern 33a1 on the side of the side portion 20b.

The wiring portion 43 extends from a lower end of the rising portion 42 to the conductive circuit pattern 33b1 across a space between an insulated circuit board 31a and an insulated circuit board 31b along the upper surface 3a and long sides of the heat dissipation base 3, and is connected to the bonding portion 44. This is the same with the first embodiment. The bonding portion 44 is connected to the other end of the wiring portion 43 and is bonded to the conductive circuit pattern 33b1. This is the same with the first embodiment. The bonding portion 44 may be integrally connected to the wiring portion 43 with a level difference therebetween.

The lead frame 50 also electrically connects an external connection terminal 25 and a conductive circuit pattern 33a2. This is the same with the first embodiment. The lead frame 50 also has a flat plate shape and integrally includes a bonding portion 51, a rising portion 52, and a bonding portion 53. Furthermore, the lead frame 50 includes a wiring portion 55.

The bonding portion 51 has an L shape in plan view and is parallel to the upper surface 3a of the heat dissipation base 3. One end of the bonding portion 51 is bonded to a bonding portion 25b of an external connection terminal 25 over the level difference 22a, and the other end is integrally connected to the rising portion 52. The bonding portion 51 extends from the one end in the −Y direction along the side portion 20b on the level difference 22a, and is bent at right angles toward the housing region 23 at a central portion in the ±Y directions of the level difference 22a. A bent portion of the bonding portion 51 extends toward the protrusion 33c of the conductive circuit pattern 33a1 and is connected to an upper end of the rising portion 52. Furthermore, the bonding portion 51 is located under the bonding portion 41 of the lead frame 40 with an insulating member 39 therebetween.

The rising portion 52 extends perpendicularly from the other end of the bonding portion 51 toward the upper surface 3a of the heat dissipation base 3 and is connected to one end of the wiring portion 55. For example, the rising portion 52 may be located over the conductive circuit pattern 33a2 in plan view. In FIG. 7, the rising portion 52 is located near an end portion of the conductive circuit pattern 33a2 on the side of the side portion 20b (in the −X direction).

One end of the wiring portion 55 is connected to a lower end of the rising portion 52 and extends from the lower end toward the conductive circuit pattern 33a1 along the upper surface 3a and the long sides of the heat dissipation base 3. The other end of the wiring portion 55 is connected to an upper end of the bonding portion 53.

One end of the bonding portion 53 is connected to the other end side of the wiring portion 55 on a side portion in the ±X directions of the wiring portion 55. Furthermore, the other end extends perpendicularly toward the upper surface 3a of the heat dissipation base 3, extends in the ±Y directions, and is then bonded to the conductive circuit pattern 33a2.

The bonding portion 41, the rising portion 42a, the wiring portion 43a, and the rising portion 42 of the lead frame 40 are superimposed over the bonding portion 51, the rising portion 52, and the wiring portion 55 of the lead frame 50 with a gap therebetween. A gap between the bonding portion 41 and the bonding portion 51 and a gap between the wiring portion 43a and the wiring portion 55 may be about 1 mm.

The portions of the lead frame 40 are superimposed over the portions of the lead frame 50. These portions of the lead frames 40 and 50 and an upper portion of the wiring portion 55 are enclosed by a wiring protection portion 39a and the lead frames 40 and 50 are integrally fixed. That is to say, as illustrated in FIG. 8, the wiring protection portion 39a seals the outside of the bonding portion 41, the rising portion 42a, and the wiring portion 43a of the lead frame 40, and seals the outside of the bonding portion 51, the rising portion 52, the wiring portion 55, and an upper portion of the bonding portion 53 of the lead frame 50. Furthermore, the wiring protection portion 39a is used to fill a gap between the bonding portion 41, the rising portion 42a, and the wiring portion 43a of the lead frame 40 and the bonding portion 51, the rising portion 52, and the wiring portion 55 of the lead frame 50.

The wiring protection portion 39a may be made of an insulating resin. The resin is, for example, a thermoplastic resin. The thermoplastic resin is, for example, polyphenylene sulfide resin, polybutylene terephthalate resin, polybutylene succinate resin, polyamide resin, or acrylonitrile butadiene styrene resin. Furthermore, an insulating filler may be added to such resin. The filler is ceramics, such as an oxide or a nitride. Specific examples of these are, respectively, aluminum oxide, and silicon nitride and boron nitride.

With the semiconductor device 1 according to Modification 1-2, as described above, a second current energizes the wiring portion 43 of the lead frame 40 in the −X direction and a first current energizes the protrusion 33c of the conductive circuit pattern 33a1 in the +X direction. As a result, inductance is reduced. In addition, the bonding portion 41, the rising portion 42a, and the wiring portion 43a of the lead frame 40 are adjacent to and opposite to the bonding portion 51, the rising portion 52, and the wiring portion 55, respectively, of the lead frame 50. A current flowing through the lead frame 50 is opposite to the direction of the second current. Therefore, inductance is further reduced in the lead frames 40 and 50. As a result, the semiconductor device 1 according to Modification 1-2 reduces inductance while realizing miniaturization compared with the first embodiment.

### Second Embodiment

In a second and later embodiments, a conductive circuit pattern, a lead frame, and a case different from those of the first embodiment will be described. The other components of each of the second and later embodiments are the same as those of the first embodiment. Furthermore, in the second and later embodiments, although illustration and description of the case are omitted, external connection terminals 24, 25, and 26 (and terminal blocks 21a, 21b, and 21c) may be located on the case in positions, shapes, and numbers corresponding to various lead frames.

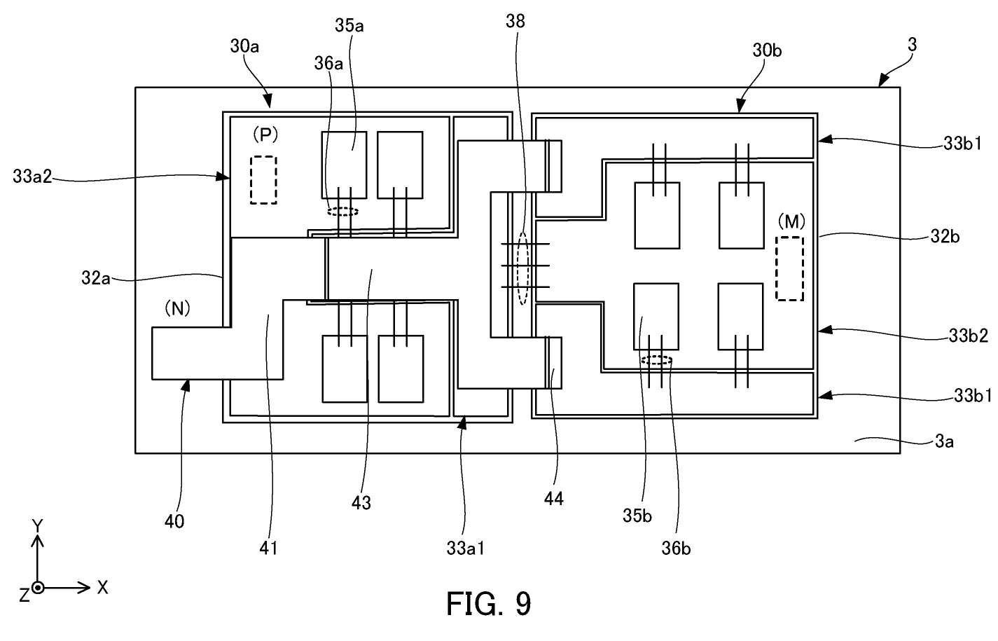

Semiconductor units 30a and 30b and a lead frame 40 formed on a heat dissipation base 3 of the second embodiment will be described with reference to FIG. 9. FIG. 9 is a plan view of insulated circuit boards on which semiconductor chips are arranged and which are arranged on the heat dissipation base 3 of the second embodiment.

As illustrated in FIG. 9, a semiconductor device according to the second embodiment includes the semiconductor units 30a and 30b and the lead frame 40 formed on the heat dissipation base 3. The structure of the semiconductor unit 30a is the same as that of the semiconductor unit 30a of the first embodiment. However, a case where the number of semiconductor chips 35a is four is illustrated. The external connection terminal 25 is electrically bonded to an area (P) surrounded by a broken line of a conductive circuit pattern 33a2.

An insulated circuit board 31b of the semiconductor unit 30b includes conductive circuit patterns 33b1 and 33b2. The conductive circuit patterns 33b1 have an L shape in plan view. The conductive circuit patterns 33b1 are formed on an insulating plate 32b so as to sandwich a conductive circuit pattern 33b2 described later from the ±Y directions. Furthermore, the conductive circuit pattern 33b2 includes a rectangular portion in plan view and a portion protruding in the −X direction from the rectangular portion. The conductive circuit pattern 33b2 is electrically connected to a conductive circuit pattern 33a1 via wires 38.

The semiconductor chips 35b are arranged in plan view in two rows and two columns on the conductive circuit pattern 33b2 with the output electrodes facing the outside (±Y directions). The output electrodes of the semiconductor chips 35b are electrically connected to the conductive circuit patterns 33b1 via wires 36b. The external connection terminal 26 is electrically bonded to an area (M) surrounded by a broken line of the conductive circuit pattern 33b2.

A wiring portion 43 of the lead frame 40 of the second embodiment differs from the wiring portion 43 of the lead frame 40 of the first embodiment. An end portion on the +X direction side of the wiring portion 43 of the lead frame 40 of the second embodiment branches in plan view into two in the ±Y directions over a portion of the conductive circuit pattern 33a1 opposite the semiconductor unit 30b. End portions branched into two extend to the conductive circuit patterns 33b1 along an upper surface 3a and the long sides of the heat dissipation base 3 across a space between the insulated circuit board 31a and the insulated circuit board 31b, and are connected to bonding portions 44. The wires 38 are bonded to the conductive circuit pattern 33a1 between the two branched portions of the wiring portion 43, so that contact with the wiring portion 43 is avoided.

With the semiconductor device including the semiconductor units 30a and 30b and the lead frame 40 formed on the heat dissipation base 3, a negative electrode of an external power supply is connected to an external connection portion 24a of the external connection terminal 24 and a positive electrode of the external power supply is connected to an external connection portion 25a of the external connection terminal 25. This is the same with the first embodiment. In response to a control signal input to the control electrodes of the semiconductor chips 35a, a first current output from the output electrodes of the semiconductor chips 35a flows through a protrusion 33c of the conductive circuit pattern 33a1 in the +X direction. This is the same with the first embodiment. The first current flows from the conductive circuit pattern 33a1 into the conductive circuit pattern 33b2 via the wires 38. The first current flowing into the conductive circuit pattern 33b2 is input to the input electrodes on the back surfaces of the semiconductor chips 35b or flows out from the external connection terminal 26.

Furthermore, the sum of the first current and a current flowing from the external connection terminal 26 is input to the input electrodes of the semiconductor chip 35b and a second current is output from the output electrodes on the upper surfaces of the semiconductor chip 35b. The second current flows into the conductive circuit patterns 33b1 via the wires 36b and flows in the −X direction. The second current flowing through the conductive circuit patterns 33b1 in the −X direction is input from the bonding portion 44 to the lead frame 40. The second current flows through the wiring portion 43 of the lead frame 40 in the −X direction.

At this time, the first current flowing through the conductive circuit pattern 33a1 (protrusion 33c) and the second current flowing through the wiring portion 43 of the lead frame 40 flow in opposite directions. This is the same with the first embodiment. Furthermore, in the second embodiment, the conductive circuit pattern 33a1 (protrusion 33c) and the wiring portion 43 of the lead frame 40 are adjacent to each other. Therefore, the inductance of wirings through which the first and second currents flow is reduced. As described above, with the semiconductor device according to the second embodiment, because the conductive circuit pattern 33a1 and the lead frame 40 are adjacent to each other, inductance is reduced.

### Third Embodiment

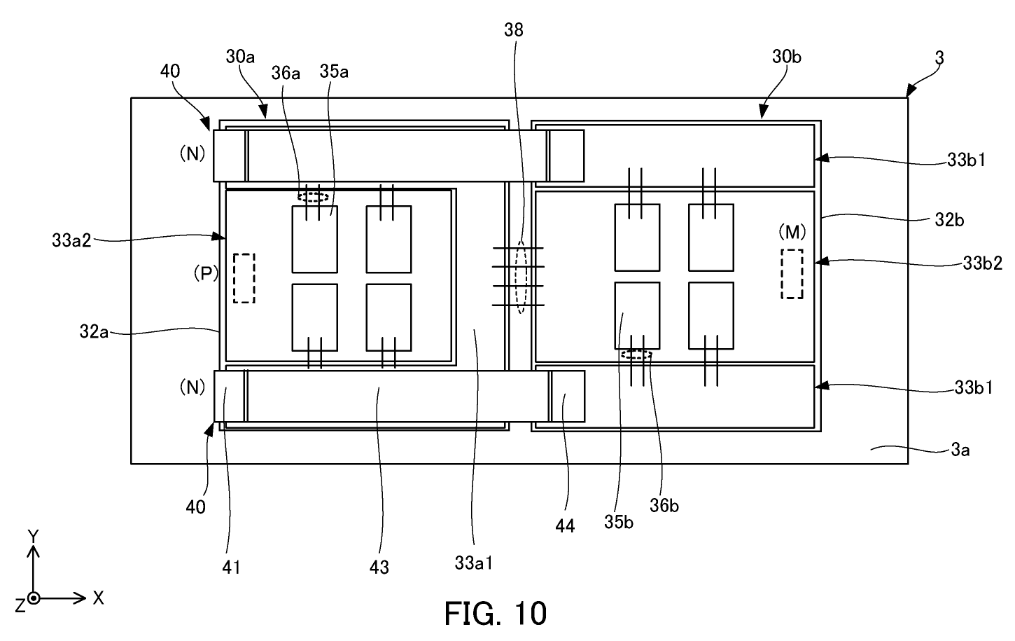

Semiconductor units 30a and 30b and lead frames 40 formed on a heat dissipation base 3 of the third embodiment will be described with reference to FIG. 10. FIG. 10 is a plan view of insulated circuit boards on which semiconductor chips are arranged and which are arranged on a heat dissipation base of a third embodiment.

As illustrated in FIG. 10, a semiconductor device according to the third embodiment includes the semiconductor units 30a and 30b and the two lead frames 40 formed on the heat dissipation base 3. An insulated circuit board 31a of the semiconductor unit 30a includes conductive circuit patterns 33a1 and 33a2. The conductive circuit pattern 33a1 has a U shape in plan view and is arranged so as to face sides in the ±Y directions and a side in the +X direction of the conductive circuit pattern 33a2 described later. The conductive circuit pattern 33a1 is electrically connected to output electrodes of semiconductor chips 35a by wires 36a.

The conductive circuit pattern 33a2 has a rectangular shape in plan view and is formed at the center of an insulating plate 32a in the −X direction. In addition, the semiconductor chips 35a are arranged in two rows and two columns in plan view with the output electrodes facing the outside (±Y directions). An external connection terminal 25 is electrically bonded to an area (P) surrounded by a broken line of the conductive circuit pattern 33a2.

The structure of the semiconductor unit 30b may be basically the same as that of the semiconductor unit 30b of the second embodiment. In the third embodiment, each of conductive circuit patterns 33b1 and 33b2 has a rectangular shape.

The two lead frames 40 electrically connect an external connection terminal 24 and the conductive circuit patterns 33b1. The lead frames 40 of the third embodiment is formed opposite portions on both sides of the conductive circuit pattern 33a1 in the ±Y directions.

The lead frames 40 have a flat plate shape, have a linear shape extending in the ±X directions, and integrally includes a bonding portion 41, a rising portion (not illustrated), a wiring portion 43, and a bonding portion 44. The bonding portions 41 of the two lead frames 40 are electrically bonded to external connection terminals 24.

The bonding portion 41 has a flat plate shape and a linear shape in plan view and is parallel to an upper surface 3a and long sides of the heat dissipation base 3. One end of the bonding portion 41 is bonded to a bonding portion 24b of the external connection terminal 24, for example, on a level difference 22a and the other end is integrally connected to the rising portion (not illustrated). The bonding portion 41 extends from the one end to a housing region 23 perpendicularly to a side portion 20b and the other end is connected to an upper end of the rising portion. The rising portion connects the bonding portion 41 and the wiring portion 43. This is the same with the rising portion 42 of the first embodiment.

The wiring portion 43 extends from a lower end of the rising portion to the conductive circuit pattern 33b1 across a space between the insulated circuit board 31a and an insulated circuit board 31b along the upper surface 3a and the long sides of the heat dissipation base 3, and is connected to the bonding portion 44. The width in the ±Y directions of the wiring portion 43 may be approximately equal to or smaller than the width in the same direction of side portions in the ±Y directions of the conductive circuit pattern 33a1.

The wire 36a may also be connected with a sufficient distance to the wiring portion 43 of the lead frame 40. As a result, insulation distance between the wire 36a and the wiring portion 43 of the lead frame 40 is maintained.

In this case, there is a gap between the wiring portions 43 and portions on both sides of the conductive circuit pattern 33a1 in the ±Y directions and the wiring portions 43 and the portions on both sides of the conductive circuit pattern 33a1 are adjacent to and opposite to each other. This is the same with the first embodiment. In addition, an insulating member (not illustrated) is formed in the gap. This is the same with the first embodiment.

The bonding portion 44 is connected to the other end of the wiring portion 43 and is bonded to the conductive circuit pattern 33b1. This is the same with the first embodiment. The bonding portion 44 may be integrally connected to the wiring portion 43 with a level difference therebetween.

With the semiconductor device including the semiconductor units 30a and 30b and the lead frames 40 formed on the heat dissipation base 3, a first current flowing through (portions on both sides of) the conductive circuit pattern 33a1 and a second current flowing through the wiring portions 43 of the lead frames 40 flow in opposite directions. This is the same with the first embodiment. Furthermore, in the third embodiment, the portions on both sides of the conductive circuit pattern 33a1 in the ±Y directions are also adjacent to the wiring portions 43 of the lead frames 40. Therefore, the inductance of wirings through which the first and second currents flow is reduced. As described above, with the semiconductor device 1, because the conductive circuit pattern 33a1 and the wiring portions 43 of the lead frames 40 are adjacent to each other, inductance is reduced.

### Fourth Embodiment

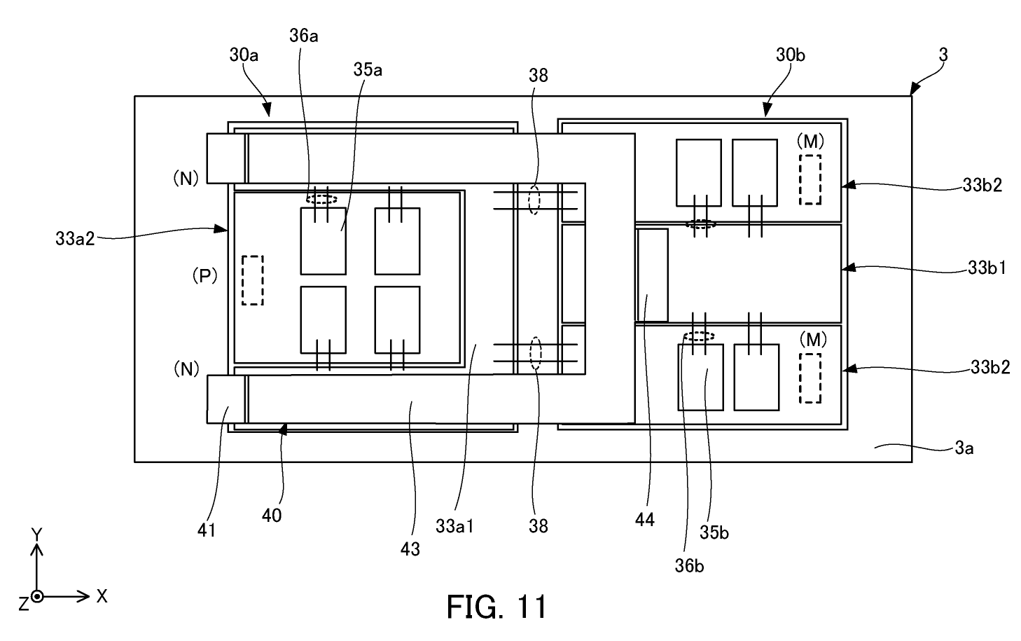

Semiconductor units 30a and 30b and a lead frame 40 formed on a heat dissipation base 3 of a fourth embodiment will be described with reference to FIG. 11. FIG. 11 is a plan view of insulated circuit boards on which semiconductor chips are arranged and which are arranged on a heat dissipation base of a fourth embodiment.

As illustrated in FIG. 11, a semiconductor device according to a fourth embodiment includes semiconductor units 30a and 30b and a lead frame 40 formed on a heat dissipation base 3. The structure of the semiconductor units 30a and 30b is the same as that of the semiconductor units 30a and 30b of the third embodiment. However, semiconductor chips 35b are arranged on conductive circuit patterns 33b2 formed on both ends in the ±Y directions of an insulated circuit board 31b of the semiconductor unit 30b. The width of the conductive circuit patterns 33b2 in the ±Y directions is approximately equal to the width of a conductive circuit pattern 33b1 in the same directions. Furthermore, in this case, the semiconductor chips 35b are arranged in plan view with output electrodes facing the conductive circuit pattern 33b1. The output electrodes of the semiconductor chips 35b and the conductive circuit pattern 33b1 are electrically connected by wires 36b. Two external connection terminals 26 are electrically connected to areas (M) indicated by broken lines of the conductive circuit patterns 33b2, respectively.

The lead frame 40 electrically connects external connection terminals 24 and the conductive circuit pattern 33b1. The lead frame 40 has a flat plate shape and integrally includes a bonding portion 41, a rising portion (not illustrated), wiring portions 43, and a bonding portion 44.

The two wiring portions 43 have a flat plate shape and a linear shape in plan view and are parallel to an upper surface 3a of the heat dissipation base 3. For example, one end of the bonding portion 41 may be bonded to bonding portions 24b of the two external connection terminals 24 on a level difference 22a, and the other end may be integrally connected to two rising portions (not illustrated). The bonding portion 41 extends from the one end to a housing region 23 perpendicularly to a side portion 20b and the other end is connected to upper ends of the rising portions. The rising portions of the fourth embodiment connect the bonding portion 41 and the wiring portions 43. This is the same with the rising portion 42 of the first embodiment.

The lead frame 40 includes the two wiring portions 43, includes a portion having a U shape in plan view, and has two end portions (in the −X direction) connected to a lower end of the rising portion. The wiring portions 43 extend from the lower end of the rising portion to the conductive circuit patterns 33b2 across a space between the insulated circuit boards 31a and 31b along the upper surface 3a and the long sides of the heat dissipation base 3. The bonding portion 44 is connected to the center of an end portion in the +X direction. The width in the ±Y directions of the wiring portion 43 may be approximately equal to or smaller than the width in the same directions of side portions in the ±Y directions of a conductive circuit pattern 33a1.

The wires 36a may also be connected with a sufficient distance to the wiring portions 43 of the lead frame 40. As a result, insulation distance between the wires 36a and the wiring portions 43 of the lead frame 40 is maintained.

There are a gap between portions of the wiring portions 43 of the lead frame 40 superimposed over the conductive circuit pattern 33a1 and portions on both sides of the conductive circuit pattern 33a1 in the ±Y directions. These portions of the wiring portion 43 and the portions on both sides of the conductive circuit pattern 33a1 in the ±Y directions are adjacent to and opposite to each other. This is the same with the first embodiment. Furthermore, an insulating member (not illustrated) is formed in the gap. This is the same with the first embodiment.

The bonding portion 44 is connected to the center of the other end of the wiring portion 43 in the +X direction and is bonded to the conductive circuit pattern 33b1. The bonding portion 44 may be integrally connected to the wiring portion 43 with a level difference therebetween.

With the semiconductor device including the semiconductor units 30a and 30b and the lead frame 40 formed on the heat dissipation base 3, a first current flowing through (portions on both sides in the ±Y directions of) the conductive circuit pattern 33a1 and a second current flowing through the portions on both sides of the wiring portion 43 of the lead frame 40 in the ±Y directions flow in opposite directions. This is the same with the first embodiment. Furthermore, in the fourth embodiment, the portions of the wiring portion 43 of the lead frame 40 superimposed over the conductive circuit pattern 33a1 are also adjacent to the conductive circuit pattern 33a1. Therefore, the inductance of wirings through which the first and second currents flow is reduced. As described above, with the semiconductor device, because the conductive circuit pattern 33a1 and the wiring portions 43 of the lead frame 40 are adjacent to each other, inductance is reduced.

### Fifth Embodiment

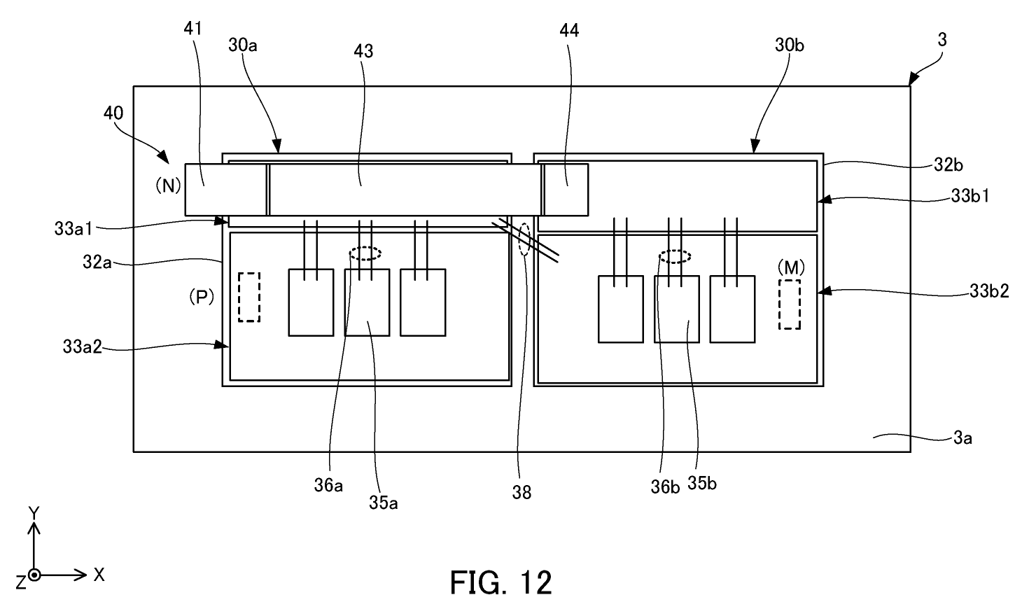

Semiconductor units 30a and 30b and a lead frame 40 formed on a heat dissipation base 3 of a fifth embodiment will be described with reference to FIG. 12. FIG. 12 is a plan view of insulated circuit boards on which semiconductor chips are arranged and which are arranged on a heat dissipation base of a fifth embodiment.

As illustrated in FIG. 12, a semiconductor device according to a fifth embodiment includes semiconductor units 30a and 30b and a lead frame 40 formed on a heat dissipation base 3. An insulated circuit board 31a of the semiconductor unit 30a includes conductive circuit patterns 33a1 and 33a2. The conductive circuit patterns 33a1 and 33a2 have a rectangular shape in plan view. The conductive circuit pattern 33a1 is formed on the +Y direction side of an insulating plate 32a and the conductive circuit pattern 33a2 is formed on the −Y direction side of the insulating plate 32a. The width of the conductive circuit pattern 33a1 in the ±Y directions may be smaller than the width of the conductive circuit pattern 33a2 in the same directions and larger than the width of the lead frame 40 in the same directions.

In addition, semiconductor chips 35a are arranged in plan view in a line in the ±X directions on the conductive circuit pattern 33a2 with output electrodes facing the conductive circuit pattern 33a1 (+Y direction). The output electrode of the semiconductor chips 35a and the conductive circuit pattern 33a1 are electrically connected by wires 36a. An external connection terminal 25 is electrically bonded to an area (P) surrounded by a broken line of the conductive circuit pattern 33a2.

An insulated circuit board 31b of the semiconductor unit 30b includes conductive circuit patterns 33b1 and 33b2. The conductive circuit patterns 33b1 and 33b2 have a rectangular shape in plan view. The conductive circuit pattern 33b1 is formed on the +Y direction side of an insulating plate 32b and the conductive circuit pattern 33b2 is formed on the −Y direction side of the insulating plate 32b.

In addition, semiconductor chips 35b are arranged in plan view in a line in the ±X directions on the conductive circuit pattern 33b2 with output electrodes facing the conductive circuit pattern 33b1 (+Y direction). The output electrode of the semiconductor chips 35b and the conductive circuit pattern 33b1 are electrically connected by wires 36b. An external connection terminal 26 is electrically bonded to an area (M) surrounded by a broken line of the conductive circuit pattern 33b2. Furthermore, the conductive circuit pattern 33a1 of the insulated circuit board 31a and the conductive circuit pattern 33b2 of the insulated circuit board 31b are electrically connected by wires 38.

The lead frame 40 electrically connects an external connection terminal 24 and the conductive circuit pattern 33b1. The lead frame 40 has a flat plate shape and a linear shape extending in the ±X directions, and integrally includes a bonding portion 41, a rising portion (not illustrated), a wiring portion 43, and a bonding portion 44. The bonding portion 41 of the lead frame 40 is electrically connected to the external connection terminal 24.

The bonding portion 41 has a flat plate shape and a linear shape in plan view and is parallel to an upper surface 3a and long sides of the heat dissipation base 3. One end of the bonding portion 41 is bonded to a bonding portion 24b of the external connection terminal 24, for example, on a level difference 22a and the other end is integrally connected to the rising portion (not illustrated). The bonding portion 41 extends from the one end to a housing region 23 perpendicularly to a side portion 20b and the other end is connected to an upper end of the rising portion. The rising portion connects the bonding portion 41 and the wiring portion 43. This is the same with the rising portion 42 of the first embodiment.

The wiring portion 43 extends over the conductive circuit pattern 33a1 from a lower end of the rising portion to the conductive circuit pattern 33b1 along the upper surface 3a and the long sides of the heat dissipation base 3 across a space between the insulated circuit boards 31a and 31b, and is connected to the bonding portion 44. The width of the wiring portion 43 in the ±Y directions may be smaller than the width of the conductive circuit pattern 33a1 in the ±Y directions.

The wires 36a may also be connected with a sufficient distance to the wiring portion 43 of the lead frame 40. As a result, insulation distance between the wires 36a and the wiring portion 43 of the lead frame 40 is maintained.

In this case, similarly to the first embodiment, there is a gap between the wiring portion 43 and the conductive circuit pattern 33a1, and the wiring portion 43 and the conductive circuit pattern 33a1 are adjacent to and opposite to each other. This is the same with the first embodiment. Furthermore, an insulating member (not illustrated) is formed in the gap. This is the same with the first embodiment.

The bonding portion 44 is connected to the other end of the wiring portion 43 and is bonded to the conductive circuit pattern 33b1. This is the same with the first embodiment. The bonding portion 44 may be integrally connected to the wiring portion 43 with a level difference therebetween.

With the semiconductor device including the semiconductor units 30a and 30b and the lead frame 40 formed on the heat dissipation base 3, a first current flowing through the conductive circuit pattern 33a1 and a second current flowing through the wiring portion 43 of the lead frame 40 flow in opposite directions. This is the same with the first embodiment. Furthermore, in the fifth embodiment, the conductive circuit pattern 33a1 and the wiring portion 43 of the lead frame 40 are also adjacent to each other. Therefore, the inductance of wirings through which the first and second currents flow is reduced. As described above, with the semiconductor device 1, because the conductive circuit pattern 33a1 and the wiring portion 43 of the lead frame 40 are adjacent to each other, inductance is reduced.

### Sixth Embodiment

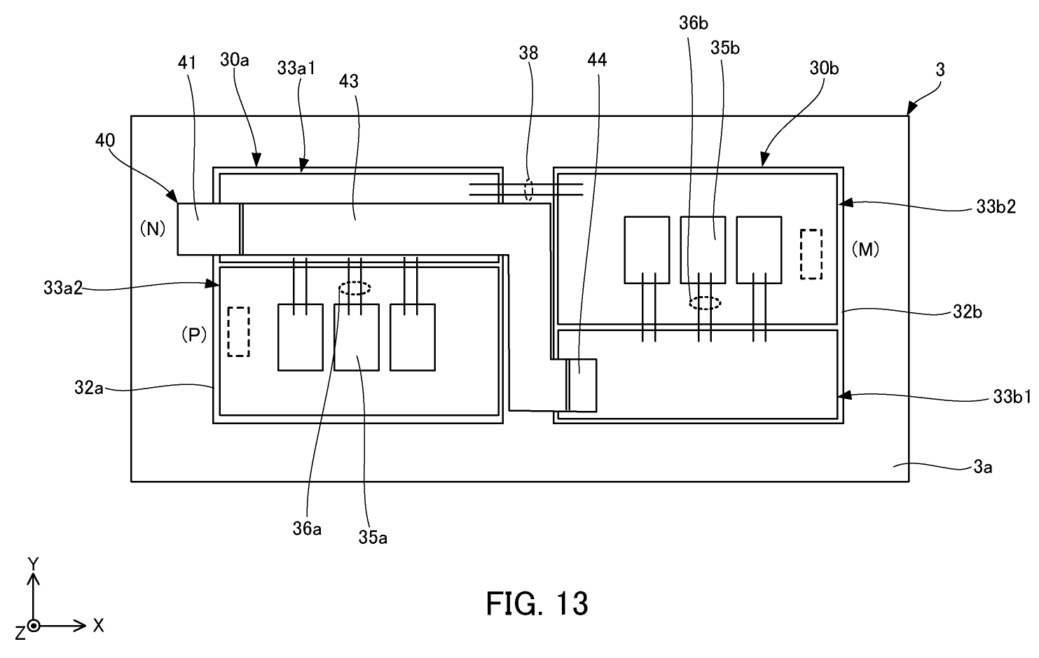

Semiconductor units 30a and 30b and a lead frame 40 formed on a heat dissipation base 3 of a sixth embodiment will be described with reference to FIG. 13. FIG. 13 is a plan view of insulated circuit board on which semiconductor chips are arranged and which are arranged on a heat dissipation base of a sixth embodiment.

As illustrated in FIG. 13, a semiconductor device according to a sixth embodiment includes semiconductor units 30a and 30b and a lead frame 40 formed on a heat dissipation base 3. An insulated circuit board 31a of the semiconductor unit 30a includes conductive circuit patterns 33a1 and 33a2. The conductive circuit patterns 33a1 and 33a2 have a rectangular shape in plan view. The conductive circuit pattern 33a1 is formed on a +Y direction side of an insulating plate 32a and the conductive circuit pattern 33a2 is formed on a −Y direction side of the insulating plate 32a. The width of the conductive circuit pattern 33a2 in the ±Y directions may be larger than the width of the conductive circuit pattern 33a1 in the same directions and may be larger than the width of the lead frame 40 in the same directions.

In addition, semiconductor chips 35a are arranged in plan view in a line in the ±X directions on the conductive circuit pattern 33a2 with output electrodes facing the conductive circuit pattern 33a1 (+Y direction). The output electrodes of the semiconductor chips 35a and the conductive circuit pattern 33a1 are electrically connected by wires 36a. An external connection terminal 25 is electrically bonded to an area (P) surrounded by a broken line of the conductive circuit pattern 33a2. The output electrodes of the semiconductor chips 35a are electrically connected to the conductive circuit pattern 33a1 by the wires 36a.

An insulated circuit board 31b of the semiconductor unit 30b includes conductive circuit patterns 33b1 and 33b2. The conductive circuit patterns 33b1 and 33b2 have a rectangular shape in plan view. The conductive circuit pattern 33b2 is formed on a +Y direction side of the insulating plate 32b and the conductive circuit pattern 33b1 is formed on a −Y direction side of the insulating plate 32b. The width of the conductive circuit pattern 33b1 in the ±Y directions may be smaller than the width of the conductive circuit pattern 33b2 in the same directions and may be larger than the width of the lead frame 40 in the same directions.

In addition, the semiconductor chips 35b are arranged in plan view in a line in the ±X directions on the conductive circuit pattern 33b2 with output electrodes facing the conductive circuit pattern 33b1 (−Y direction). The output electrodes of the semiconductor chips 35b and the conductive circuit pattern 33b1 are electrically connected by wires 36b. An external connection terminal 26 is electrically bonded to an area (M) surrounded by a broken line of the conductive circuit pattern 33b2. Furthermore, wires 38 electrically connect the conductive circuit pattern 33a1 and the conductive circuit pattern 33b2.

The lead frame 40 electrically connects an external connection terminal 24 and the conductive circuit pattern 33b1. The lead frame 40 has a flat plate shape, has a crank shape in plan view, and integrally includes a bonding portion 41, a rising portion (not illustrated), a wiring portion 43, and a bonding portion 44. The bonding portion 41 of the lead frame 40 is electrically connected to the external connection terminal 24.

The bonding portion 41 has a flat plate shape and a linear shape in plan view and is parallel to an upper surface 3a and long sides of the heat dissipation base 3. One end of the bonding portion 41 is bonded to a bonding portion 24b of the external connection terminal 24, for example, on a level difference 22a and the other end is integrally connected to the rising portion (not illustrated). The bonding portion 41 extends from the one end to a housing region 23 perpendicularly to a side portion 20b and the other end is connected to an upper end of the rising portion. The rising portion connects the bonding portion 41 and the wiring portion 43. This is the same with the rising portion 42 of the first embodiment.

The wiring portion 43 may have, for example, an L shape in plan view. The wiring portion 43 extends over the conductive circuit pattern 33a1 from a lower end of the rising portion toward a space between the insulated circuit boards 31a and 31b along the upper surface 3a and the long sides of the heat dissipation base 3. The wiring portion 43 is bent at right angles in the −Y direction between the insulated circuit board 31a and the insulated circuit board 31b and extends in the −Y direction. The width in the ±Y directions of a portion of the wiring portion 43 superimposed over the conductive circuit pattern 33a1 may be approximately equal to or smaller than the width in the same directions of the conductive circuit pattern 33a1.

In this case, there is a gap between the wiring portion 43 and the conductive circuit pattern 33a1 and the wiring portion 43 and the conductive circuit pattern 33a1 are adjacent to and opposite to each other. This is the same with the first embodiment. In addition, an insulating member (not illustrated) is formed in the gap. This is the same with the first embodiment.

The bonding portion 44 is connected to a portion of the wiring portion 43 extending in the −Y direction and is bonded to the conductive circuit pattern 33b1. The bonding portion 44 may be integrally connected to the wiring portion 43 with a level difference therebetween.

With the semiconductor device including the semiconductor units 30a and 30b and the lead frame 40 formed on the heat dissipation base 3, a first current flowing through the conductive circuit pattern 33a1 and a second current flowing through the wiring portion 43 of the lead frame 40 flow in opposite directions. This is the same with the first embodiment. Furthermore, in the sixth embodiment, the conductive circuit pattern 33a1 and the wiring portion 43 of the lead frame 40 are also adjacent to each other. Therefore, the inductance of wirings through which the first and second currents flow is reduced. As described above, with the semiconductor device 1, because the conductive circuit pattern 33a1 and the wiring portion 43 of the lead frame 40 are adjacent to each other, inductance is reduced.

According to the disclosed techniques, inductance is reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first output conductive plate through which a first current flows in a first direction; and
a wiring member, including:
a bonding portion at one end thereof, to which a second current is input, and
a wiring portion which is arranged to be adjacent to and opposite to an upper surface of the first output conductive plate and through which the second current input to the bonding portion flows in a second direction opposite to the first direction.

2. The semiconductor device according to claim 1 further comprising a second output conductive plate to which the bonding portion of the wiring member is electrically connected and through which the second current input to the bonding portion flows.

3. The semiconductor device according to claim 2 further comprising:
a first insulated circuit board, including:
a first insulating plate, and
the first output conductive plate, formed on an upper surface of the first insulating plate; and
a first semiconductor chip arranged on the first insulated circuit board and including a first output electrode configured to output the first current to the first output conductive plate.

4. The semiconductor device according to claim 3 further comprising:
a second insulated circuit board, including:
a second insulating plate, and
the second output conductive plate, formed on an upper surface of the second insulating plate; and
a second semiconductor chip arranged on the second insulated circuit board and including a second output electrode configured to output the second current to the second output conductive plate.

5. The semiconductor device according to claim 4, wherein:
the first semiconductor chip has a first input electrode;
the second semiconductor chip has a second input electrode;
the first insulated circuit board further includes a first input conductive plate, which is formed on the upper surface of the first insulating plate, and is electrically connected to the first input electrode of the first semiconductor chip; and
the second insulated circuit board further includes a second input conductive plate, which is formed on the upper surface of the second insulating plate, is electrically connected to the second input electrode of the second semiconductor chip, and is electrically connected to the first output conductive plate.

6. The semiconductor device according to claim 5, wherein the first input conductive plate of the first insulated circuit board is connected to a positive power supply terminal.

7. The semiconductor device according to claim 5, wherein the wiring member further has a connection portion at another end thereof, the connection portion being connected to a negative power supply terminal.

8. The semiconductor device according to claim 1, wherein the wiring portion of the wiring member and the first output conductive plate have a gap formed therebetween that is 3 mm or less.

9. The semiconductor device according to claim 8, wherein the gap between the wiring portion of the wiring member and the first output conductive plate is 1 mm.

10. The semiconductor device according to claim 8, further comprising an insulating member formed in the gap between the wiring portion of the wiring member and the first output conductive plate.

11. The semiconductor device according to claim 10, wherein the insulating member is an insulating sheet.

12. The semiconductor device according to claim 11, wherein the insulating member has an adhesive layer formed on one main surface of the insulating sheet.

13. The semiconductor device according to claim 1, wherein:
the first output conductive plate has at least a portion thereof extending in the first direction;
the wiring portion of the wiring member extends in the second direction; and
the wiring portion is arranged to be opposite to the portion of the first output conductive plate extending in the first direction.

14. The semiconductor device according to claim 13, wherein
the wiring portion of the wiring member is of a first length in a first width direction perpendicular to the second direction; and
the portion of the first output conductive plate extending in the first direction is of a second length in a second width direction perpendicular to the first direction, the first length being smaller than the second length.
